(19) United States
(12) Patent Application Publication
(10) Pub. No.: US 2008/0084255 A1
(43) Pub. Date: Apr. 10, 2008

(54) Integrated circuit arrangement and use of connecting lines

(76) Inventors: Samir El Rai, Colorado Springs, CO (US); Ralf Tempel, Dulsburg (DE)

Correspondence Address: MG-IP Law, PLLC, P.O. BOX 1364, FAIRFAX, VA, 22038-1364, US

(21) Appl. No.: 11/902,479

(22) Filed: Sep. 21, 2007

(30) Foreign Application Priority Data
Sep. 21, 2006 (DE) DE 102006044570

(51) Int. Cl. H01F 27/30; H01F 41/10; H03H 7/00

(52) U.S. Cl. 333/185; 29/602.1; 336/186; 336/73

(57) ABSTRACT

An integrated circuit arrangement and a use of connecting lines is provided. The integrated circuit arrangement has an inductive unit and a circuit component, wherein the inductive unit has a first inductor with a first coil and first connecting lines, wherein the first connecting lines connect the first coil to the circuit component, wherein the inductive unit has at least one second inductor that is connected in parallel to the first inductor and that has a second coil and second connecting lines, wherein the second connecting lines connect the second coil to the circuit component, and wherein the circuit component is arranged between the first coil and the second coil.

This nonprovisional application claims priority under 35 U.S.C. § 119(a) to German Patent Application No. DE 102006044570, which was filed in Germany on Sep. 21, 2007, and which is herein incorporated by reference.

### BACKGROUND OF THE INVENTION

1. Field of the Invention

The present invention relates to an integrated circuit arrangement. The invention further relates to a use of connecting lines.

2. Description of the Background Art

The invention resides in the field of integrated semiconductor circuits (integrated circuit, IC), in which high-frequency signals, for example in the microwave range, are processed. In particular, it resides in the field of integrated circuit arrangements with integrated inductors (conductor loops, “coils”), which must have very small predefined inductance values below approximately 1 nH (nanohenry). Such coils are frequently needed for processing high-frequency (HF) signals, for example in integrated HF front-end circuits by means of which a received HF signal, as for example a radio signal in the gigahertz range received through an antenna, is converted into a quadrature signal having a lower, fixed frequency in the transmitting/receiving devices of communications systems. The coils here are, for example, part of amplifiers, oscillators or filters.

A variety of problems arise in the implementation of integrated circuit arrangements having such a coil and at least one other circuit component that is connected to the coil and is likewise integrated.

Thus, for example, the connecting lines through which the coil is connected to the other circuit components can themselves have a length and thus an inductance that is in the same order of magnitude as the predefined inductance value or even exceeds it, so that the coil cannot actually be connected to the circuit components. In every case, the connecting line inductances further reduce the already very small inductance value of the coil that is to be implemented, so that in some cases a coil with an extremely small inductance value, e.g. in the range of tens of pH (picohenries) must be implemented.

The connecting lines are frequently located in a metallization of the integrated circuit that has a smaller layer thickness than the metallization in which the trace for the coil is implemented. Furthermore, the connecting lines frequently have a smaller trace width than the trace for the coil. The quality factor of the connecting line inductances is thus generally lower than the quality factor of the actual coil, so that the circuit arrangement has an overall quality factor that can be lower than the quality factor of the coil itself.

For very small inductance values, it may in some cases be impossible to geometrically produce the coil because the required length of its connecting lines is so short that the design rules of the production technology do not allow a closed figure.

Integrated inductors are known from U.S. Pat. No. 6,320,491 B1. Here, coils are connected in series or parallel, with the current in adjacent conductor segments of the coils flowing in opposite directions. The coils are provided with connecting line strips that permit connection to additional components.

### SUMMARY OF THE INVENTION

It is therefore an object of the present invention to provide an integrated circuit arrangement that is as simple as possible to implement and has the highest possible quality factor even for very small inductance values.

Accordingly, an integrated circuit arrangement having an inductive unit and a circuit component is provided. The inductive unit has a first inductor with a first coil and first connecting lines. The first connecting lines connect the first coil to the circuit component. The inductive unit has, connected in parallel with the first inductor, at least one second inductor with a second coil and second connecting lines. The second connecting lines connect the second coil to the circuit component. The circuit component is located between the first coil and the second coil.

It is also the object of the invention to specify an application of connecting lines for an integrated circuit arrangement. This object is attained according to the invention by an application of connecting lines.

Accordingly, an application of connecting lines is provided wherein capacitors of an LC resonant circuit are connected to the connecting lines in order to connect to a first coil and to connect to a second coil of the LC resonant circuit. The connecting lines are used to connect the first coil and the second coil of the LC resonant circuit in parallel.

According to an embodiment, first connecting lines and second connecting lines are arranged between the first coil and the second coil. Accordingly, the first coil and the second coil are separated from one another by at least a portion of the length of the connecting lines. In this context, the distance affects a magnetic interaction between the first coil and the second coil.

In another embodiment, provision is made that a closed structure is formed by the first connecting lines and the second connecting lines and the first coil and the second coil. The circuit component is preferably arranged within the closed structure. The closed structure preferably has no crossings of a conductor of the first coil with a conductor of the second coil. The closed structure is advantageously embodied in one metallization level.

According to an embodiment, the circuit component has a capacitive unit. The capacitive unit is preferably connected in parallel with the first coil and in parallel with the second coil. The capacitive unit preferably forms an LC resonant circuit together with the first coil and the second coil.

In another embodiment, provision is made that multiple capacitors of the capacitive unit are connected to the first connecting lines and to the second connecting lines at different connection points. The connection points are located along a length of the first connecting lines and along a length of the second connecting lines. The capacitors are advantageously connected over the entire length of the first lines and the second lines. The capacitors are preferably connected to one another by the connecting lines, and in particular are connected in parallel. The connection points are preferably arranged symmetrically about an axis of symmetry extending between the first inductor and the second inductor.

Preferably, one connecting line of the first connecting lines and one connecting line of the second connecting lines are designed to be adjacent to one another. Alternatively or in combination, the connecting line of the first connecting lines and the connecting line of the second connecting lines form a conductor segment produced as one piece.

According to a variant embodiment, the circuit component projects partially into the interior of the coils. In this context, the circuit component preferably has means for symmetrical operation of the inductors.

According to an embodiment, the first coil and the second coil are designed such that their inductances L1 and L2 essentially match a difference between the predefined inductance value L multiplied by the number N of inductors and an effective inductance value of all connecting lines.

In an embodiment, the first coil and the second coil are designed such that their inductance values L1 and L2 deviate by a maximum of 30% from the difference N*L−Lz_eff. In an especially advantageous embodiment, the first and second inductors take on inductance values that differ from one another by at most 20%. By this means, especially high overall quality factors are achieved for the circuit arrangement, and coils are achieved that can be connected and integrated even for extremely small predefined inductance values.

In another embodiment, the first and second coils each have at least one loop of a conductive trace. This permits a further increase in the coils' quality factor and thus the overall quality factor of the circuit arrangement.

In another embodiment, the first and second coils are designed to be identical or symmetrical to one another. Preferably, the first and second inductances, i.e. the coils and the connecting lines, are designed to be identical or symmetrical to one another. In this regard, an axially symmetric or point symmetric design is advantageous.

In an embodiment, exactly one second inductor is provided, i.e., N=2. Such circuit arrangements advantageously require a relatively small chip area of the integrated circuit.

In another embodiment, the circuit component contains a capacitive unit that preferably has at least one metal-insulator-metal (MIM) capacitor, a varactor, a switched MIM capacitor, or a switched capacitor bank (CDAC). By this means it is possible to implement, for example, integrated resonant circuits that have a high overall quality factor and low tolerances, even for very low values of the inductance.

In typical embodiments, the circuit arrangement is designed as a monolithic integrated circuit, as a hybrid circuit, or as a multilayer ceramic circuit.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a first exemplary embodiment of an inventive circuit arrangement;

FIG. 2 is a second exemplary embodiment of an inventive circuit arrangement;

FIG. 3 is a third exemplary embodiment of an inventive circuit arrangement; and

FIG. 4 is a fourth exemplary embodiment of an inventive circuit arrangement.

### DETAILED DESCRIPTION

In the figures, like and functionally like elements and signals are provided with the same reference symbols, unless otherwise indicated.

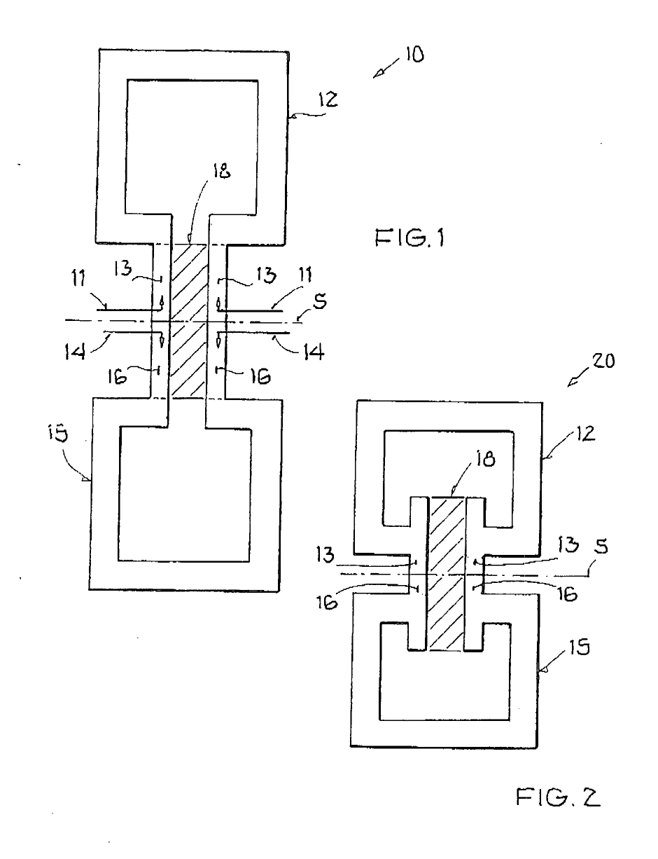

FIG. 1 schematically shows a layout of a first exemplary embodiment of an inventive circuit arrangement.

The integrated circuit arrangement 10 contains an inductive unit encompassing reference numbers 11-16 that has a predefined inductance value L, and also contains an (additional) circuit component 18 connected to the inductive unit.

The circuit component 18 can have a capacitive unit C1 that contains, for example, at least one metal-insulator-metal (MIM) capacitor, a varactor, a switched MIM capacitor, or a switched capacitor bank (CDAC). Such a circuit arrangement implements an integrated resonant circuit (LC resonant circuit) for an amplifier or oscillator, for example. In additional embodiments, the circuit component 18 has at least one transistor.

The inductive unit 11-16 contains a first inductor 11 with a first coil 12 and first connecting lines 13, as well as a second inductor 14 that is connected in parallel with the first inductor 11 and that has a second coil 15 and second connecting lines 16, wherein the coils 12, 15 have an inductance value L1 or L2 and the connecting lines 13, 16 connect the coils 12, 15 to the circuit component 18.

The coils 12, 15 are designed such that their inductance values L1 or L2 are each essentially equal to twice the predefined inductance value L minus the effective (total) inductance value Lz_eff of all connecting lines 13, 16:
L1≈2*L−Lz_eff, and L2≈2*L−Lz_eff. (1)

In an embodiment, the coils 12, 15 are designed such that they have inductance values L1, L2 that are as closely matched as possible.

In additional embodiments, the inductance values L1, L2 of the coils 12, each deviate from the difference 2*L−Lz_eff by a maximum of 30%. Preferably, the inductance values of the first and second inductors 11, 14 differ from one another by at most 20%.

As can be seen from FIG. 1, the circuit component 18 is arranged between the two coils 12, 15, so that connecting line inductances and thus the value of Lz_eff are kept as small as possible. Furthermore, the circuit component 18 is connected in parallel with the inductors 11, 14 and the coils 12, 15.

The circuit arrangement 10 with its constituents 12, 13, 15, 16, and 18, is integrated into an integrated circuit (IC), which is implemented, for example, in a 0.35 μm BiCMOS technology.

As can be seen from FIG. 1, each of the two coils 12, 15 has a loop (a turn) of a conductive trace that is arranged in a metallization level of the integrated circuit corresponding to the plane of the drawing.

The coils 12, 15 and/or the inductors 11, 14 are preferably designed to be identical or symmetrical to one another. The circuit arrangement 10 is thus designed to be symmetrical about a symmetry plane, shown in FIG. 1 by the symmetry axis S, that is perpendicular to the coil plane and that extends between the two coils.

The information below relates by way of example to an integrated circuit arrangement 10, implemented by the applicant in a 0.35 μm BiCMOS technology, with an inductive unit 11-16 and a capacitive unit 18, as shown in FIG. 1. If the inductive unit 11-16 is to have a predetermined (total) inductance value of L=200 pH, for example, wherein each of the total of four connecting lines 13, 16 has a trace section (length e.g. 100 μm, width e.g. 16 μm) with an inductance value of Lz=50 pH, then the inductance values L1, L2 of the coils 12, 15 according to Equation (1) are:
Ls=L1=L2=2*L−Lz_eff=2*200 pH−50 pH=350 pH, (2)

where identical inductance values L1=L2 are assumed in order to simplify the representation, and a coil inductance value Ls is introduced. In Equation (2), the effective (total) inductance value Lz_eff=50 pH of the connecting lines 13, 16 results from a parallel connection of the connecting line pair 13 with the connecting line pair 16, i.e. from a parallel connection of two inductors, each having a value of 2*Lz=2*50 pH=100 pH.

Coils having an inductance value of Ls=350 pH can be implemented with relatively high quality factors in a 0.35 μm BiCMOS technology, and have, for example—as shown in FIG. 1—one loop (turn) of a trace, wherein the trace has, e.g., a width of 24 μm and, a length, when straightened, of approximately 450 μm.

If Qs and Qz designate the quality factors of the coils 12, 15 and the connecting lines 13, 16, the following relationship results for the overall quality factor Q of the circuit arrangement 10:
Q=(Qs*Ls+Qz*2*Lz)/(Ls+2*Lz). (3)

Assuming a coil quality factor of, e.g., Qs=10 and a connecting line quality factor of, e.g., Qz=5, the overall quality factor Q according to Equation (3) with the above-mentioned values for Ls and Lz is:
Q=(10*350 pH+5*100 pH)/(350 pH+100 pH)=8.88, (4)

In other words the overall quality factor Q is approximately 89% of the coil quality factor Qs=10.

For instance, if tolerances of ±1 μm in the width of the coil and connecting line traces arise in the course of the production process, then the inductance values of the coils will vary in the range of approximately 350 pH±3 pH and the inductance values of the connecting lines will vary in the range of approximately 50 pH±1.5 pH. The total inductance value L thus varies in the range of approximately 200 pH±2.2 pH, which corresponds to a percentage tolerance of approximately 1%.

In addition to the circuit component 18, the first connecting lines 13 and the second connecting lines 16 are also arranged between the first coil 12 and the second coil 15. In this regard, the first connecting lines 13 are designed to be axially symmetric to the second connecting lines 16 about the line S. The first coil 12 and the second coil 15 and the first connecting lines 13 and the second connecting lines 16 form a closed structure here. The circuit component 18 is arranged inside this closed structure.

For an LC resonant circuit, the circuit component 18 has multiple capacitors. These capacitors are connected to the first connecting lines 13 and the second connecting lines 16 at different connection points. In order to simplify the explanation, this is not shown in FIG. 1. The connection points are preferably arranged symmetrically with respect to the symmetry axis S. The capacitors are connected through the connection points over a total length of the connecting lines 13, 16.

In the example embodiment in FIG. 1, one connecting line of the first connecting lines 13, together with one connecting line of the second connecting lines 16, forms a conductor segment produced as one piece. Each coil 12, 15 is formed at and electrically connected to a different end of the conductor segment produced as one piece. However, because of the symmetrical design of the inductors 11, 14, the current through each coil 12, 15 flows only through the connecting lines 13, 16 belonging to the coil 12, 15, and not through the connecting lines of the other coil (12, 15). As a result of this surprising effect, the connecting line inductances of the connecting lines 13, 16 each contribute only one half with regard to the total current through the inductive unit.

At least two (N≧2) inductors according to FIG. 1, each of which has a coil and the associated connecting lines, are connected in parallel, and their coils are designed such that their inductance values (each) correspond essentially to the difference N*L−Lz_eff, where Lz_eff designates the effective (total) inductance value of all connecting lines.

As a result of the example embodiment from FIG. 1, the disadvantageous influence of connecting line inductances on the inductance value of the coils that are to be implemented is reduced: on account of the lower effective connecting line inductance, the higher inductance value of the coils that are to be implemented is reduced to a lesser degree, so that the coils can still be connected to the circuit component and integrated even for very small predefined inductance values. The disadvantageous effect of the connecting line quality factor on the total quality factor of the circuit arrangement is reduced as well. Moreover, production-related tolerances have a less pronounced effect on the predefinable inductance value L. In addition, the coils become simpler (or possible at all) to integrate with the relevant production technology and have a higher quality factor, since, for example, the conductive trace for the coil is now long enough that the design rules permit a closed figure and/or the increased coil diameter reduces electromagnetic losses.

In order to implement the same predefined total inductance value (L=200 pH) with the same boundary conditions, prior art circuit arrangements, in which a coil is connected to a capacitive unit through connecting lines, but in which no second coil connected in parallel is provided, require implementing a coil with an inductance value of
Ls=L−Lz_eff=200 pH−100 pH=100 pH, (5)

since the effective inductance value Lz_eff of the connecting lines in this case is 100 pH. With the cited technology, a coil with an inductance value of only 100 pH is very difficult to implement, since such a coil has high losses, among other things.

Even if it were possible to implement such a coil with the same quality factor of Qs=10 (which is not the case), such a prior art circuit arrangement would have a total quality factor of
Q=(10*100 pH+5*100 pH)/(100 pH+100 pH)=7.5, (6)

which corresponds to only a 75% fraction of the assumed coil quality factor. The total quality factor achieved in accordance with the invention per Equation (4) is thus at least 18% higher than the total quality factor achieved per Equation (6).

If tolerances of ±1 μm in the trace width also arise here in the production process, the inductance value of the coil will vary in a range of approximately 100 pH±3 pH, and the inductance value of the connecting lines will likewise vary in a range of approximately 100 pH±3 pH. The total inductance value L thus varies in a range of approximately 200 pH±6 pH, corresponding to a percent tolerance of approximately 3%. Thus, production tolerances in the inventive circuit arrangement have a considerably smaller effect on the total inductance value L in terms of absolute value as well as in terms of percentage.

FIG. 2 schematically shows a layout of a second exemplary embodiment of an inventive circuit arrangement.

As compared to the first embodiment described above, the two coils 12, of the circuit arrangement 20 have a smaller spacing from one another, so that the length and thus the inductance value Lz of the connecting lines 13, 16 effectively drop. The circuit component 18, which is again arranged between the two coils 12, 15 and is designed in accordance with the description above, projects partially into the interior of the coils, which is to say into the area bounded by the loop of the trace in question.

If the inductance value of the connecting lines 13, 16 is reduced by this means to Lz=25 pH, for example, then it follows from Equation (1) that
L1≈L2≈2*L−Lz_eff=2*200 pH−25 pH=375 pH. (7)

The circuit arrangement 20 is also designed to be symmetrical about a symmetry plane, shown in FIG. 2 by a symmetry axis S, that is perpendicular to the coil plane and that extends between the two coils.

The example embodiments described above with reference to FIGS. 1 and 2 have coils 12, 15, each with one conductor loop, i.e. with essentially one turn, which is designed to be square or rectangular. In other embodiments, the conductor loops or their turns take on an essentially round or oval shape, or are designed to be piecewise straight or polygonal.

In other embodiments, more conductor loops are provided in each case, or the conductor loops each have more than one turn, which are also designed to be essentially piecewise straight, polygonal, round, oval, square, rectangular, etc. This permits a further increase in the coil quality factor and thus the overall quality factor of the circuit arrangement. Such an example embodiment is described below with reference to FIG. 3.

FIG. 3 schematically shows a layout of a third example embodiment of an inventive circuit arrangement. In the circuit arrangement 30, each of the two coils 12, has more than one loop (turn) of a trace. Each coil has a total of three partially nested loops of a trace, which are arranged in a first metallization level M1 of the integrated circuit. Located in a second metallization level M2 of the integrated circuit are the connecting lines 13, 16 that serve to connect the coils to the (additional) circuit component 18. The circuit component 18, which is designed in accordance with the example embodiments described above, is again arranged between the two coils 12, 15.

The two coils 12, 15 are designed such that their inductance values L1 and L2 according to Equation (1) are each essentially equal to twice the predefined inductance value L minus the effective (total) inductance value Lz_eff of all connecting lines 13, 16. In a preferred embodiment, the coils 12, 15 are designed such that they have inductance values L1, L2 that are as closely matched as possible.

The circuit arrangement 30 is also designed to be symmetrical about a symmetry plane, shown in FIG. 3 by a symmetry axis S, that is perpendicular to the plane of the drawing and that extends between the two coils.

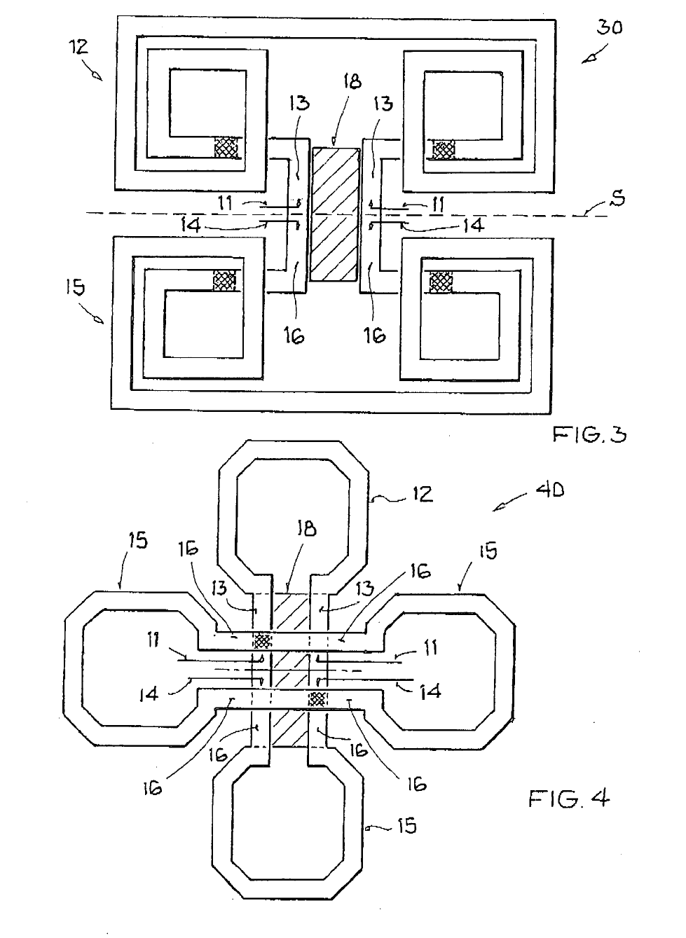

In contrast to the example embodiments described above, the inductive unit 11-16 can have not only exactly one second inductor 14 in addition to the first inductor 11, but can also have multiple second inductors 14, each of which is connected in parallel with the first inductor 11. Such an example embodiment is described below with reference to FIG. 4.

If N represents the total number of first and second inductors 11, 14 or first and second coils 12, 15, where N≧2, then the coils 12, 15 are designed such that their inductance values L1, L2 are each essentially equal to the difference of the predefined inductance value L multiplied by N minus the effective (total) inductance value Lz_eff of the connecting lines 13, 16:
L1≈N*L−Lz_eff, and L2≈N*L−Lz_eff. (8)

The coils 12, 15 preferably also have inductance values L1, L2 that are as closely matched as possible. In additional embodiments, the inductance values L1, L2 of the coils 12, 15 each deviate from the aforementioned difference N*L−Lz_eff by a maximum of 30%. Preferably, the inductance values of the first and second inductors 11, 14 differ from one another by at most 20%.

FIG. 4 schematically shows a layout of a fourth example embodiment of an inventive circuit arrangement with a total of N=4 inductors connected in parallel.

The inductive unit 11-16 of the integrated circuit arrangement 40 contains a first inductor 11 with a first coil 12 and first connecting lines 13, as well as a total of three second inductors 14, each connected in parallel with the first inductor 11 and each having a second coil 15 and second connecting lines 16, wherein the connecting lines 13, 16 connect the N=4 coils 12, 15 to the circuit component 18.

The first inductor 11 and the second inductor 14 shown below it are arranged in a first metallization level M1 of the integrated circuit, while the second inductances 14 shown on the right and left are located in a second metallization level M2. The metallization levels M1 and M2 are connected together in a conductive manner by feedthroughs in the gray-shaded crossing areas of the connecting lines 13, 16.

As can be seen from FIG. 4, the circuit component 18 is arranged between the first coil 12 and one of the second coils 15.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated circuit arrangement comprising:
an inductive unit having a first inductor with a first coil and first connecting lines, and having at least one second inductor that is connected in parallel to the first inductor and that has a second coil and second connecting lines; and
a circuit component,
wherein the first connecting lines connect the first coil to the circuit component,
wherein the second connecting lines connect the second coil to the circuit component, and
wherein the circuit component is arranged between the first coil and the second coil.

2. The circuit arrangement according to claim 1, wherein the first connecting lines and the second connecting lines are arranged between the first coil and the second coil.

3. The circuit arrangement according to claim 1, wherein a closed structure is formed by the first connecting lines and the second connecting lines and the first coil and the second coil, and wherein the circuit component is arranged within the closed structure.

4. The circuit arrangement according to claim 1, wherein the circuit component has a capacitive unit.

5. The circuit arrangement according to claim 4, wherein multiple capacitors of the capacitive unit are connected at different connection points along a length of the first connecting lines and along a length of the second connecting lines.

6. The circuit arrangement according to claim 4, wherein the capacitive unit has at least one metal-insulator-metal capacitor, a varactor, a switched MIM capacitor, or a switched capacitor bank.

7. The circuit arrangement according to claim 1, wherein one connecting line of the first connecting lines and one connecting line of the second connecting lines are adjacent to one another or form a conductor segment produced as one piece.

8. The circuit arrangement according to claim 1, wherein the first and second inductors are identical or symmetrical to one another.

9. The circuit arrangement according to claim 1, wherein the inductance values of the first and second inductors differ from one another by at most 20%.

10. The circuit arrangement according to claim 1, wherein the circuit component projects partially into the interiors of the coils.

11. The circuit arrangement according to claim 1, wherein the first and second coils each have at least one loop of a trace.

12. The circuit arrangement according to claim 1, wherein the circuit component is connected in parallel with the first coil and the second coil.

13. The circuit arrangement according to claim 1, wherein the circuit component has a transistor.

14. The circuit arrangement according to claim 1, wherein the circuit arrangement is a monolithic integrated circuit, a hybrid circuit, or a multilayer ceramic circuit.

15. Connecting lines for a parallel connection of a first coil and a second coil of an LC resonant circuit, wherein capacitors of an LC resonant circuit are connected with the connecting lines for connection to the first coil and for connection to the second coil of the LC resonant circuit.

16. A method of forming an integrated circuit arrangement, the method comprising:
providing a first inductor having a first coil and first connecting lines, the first connecting lines connecting the first coil to a circuit component;
providing a second inductor having a second coil and second connecting lines, the second connecting lines connecting the second coil to the circuit component; and
operably connecting the second inductor to the first inductor in parallel such that the circuit component is provided substantially between the first inductor and the second inductor.

17. The method according to claim 16, wherein the first inductor and the second inductor are substantially identical and/or symmetrical to one another.
